(19) United States
(12) Patent Application Publication
(10) Pub. No.: US 2002/0026754 A1
(43) Pub. Date: Mar. 7, 2002

(54) Anti-theft device

(76) Inventors: Kenneth Harold Acketts, Billericay (GB); Ronald Lionel Acketts, Hockley (GB)

Correspondence Address: GOTTLIEB RACKMAN & REISMAN PC, 270 MADISON AVENUE, 8TH FLOOR, NEW YORK, NY, 100160601

(21) Appl. No.: 09/942,814

(22) Filed: Aug. 30, 2001

(30) Foreign Application Priority Data
Aug. 30, 2000 (GB) 0021288.6

(51) Int. Cl. E04H 1/14; E04H 6/06; B66B 9/00; E04H 1/00; E04H 3/00; E04H 9/00; H03M 11/00; H03K 17/94; E04H 5/00; E04H 6/00; E04H 14/00; G06F 1/16; H05K 5/00; H05K 7/00

(52) U.S. Cl. 52/27.5; 52/29; 52/79.1; 52/79.9; 109/2; 341/22; 361/680

(57) ABSTRACT

An anti-theft device for securing an A.T.M. to a floor comprises a first beam which is secured to the floor by an overlapping beam. The beam sits in a recess in the beam, and is allowed limited free movement. The A.T.M. is secured to the beam. A plate, carrying a surrounding frame, lays between the beam and the A.T.M. The frame inhibits access to the securing plate.

### BACKGROUND

A.T.M.s which are mounted in a building wall, on public view, are typically mounted on a frame which provides little resistance to the theft of the complete machine. A fork-lift truck or an excavator can be used to lift or pull the machine out of the wall.

In GB-A-2 268 542 and GB-A-2 299 619 we describe anti-left devices which secure the A.T.M. to the floor and resist theft of the machine for sufficiently long to enable police to arrive on the scene. These devices operate by bolting the A.T.M. to a beam which in turn is bolted to the floor via brackets. The mounting between the beam and the brackets allows limited movement, which is better at resisting force of the excavator bucket, etc., than a rigid mounting.

When a free standing A.T.M. is installed within a bank or shop, it forms a complete unit which rests on the floor. Thus, there is not sufficient room at the base of the A.T.M. to fit our prior designs of anti-theft device.

### SUMMARY OF THE INVENTION

The present invention provides an anti-theft device for securing an A.T.M. to a floor comprising a first beam to which the A.T.M. is to be secured, and means for securing the beam to the floor, the securing means allowing limited free movement of the first beam.

Preferably the securing means is second beam which overlays the first beam, forming a generally cross-shape. Preferably recesses are formed in the beams where they cross, to form a halving-type joint. The joint tolerance is set to allow a degree of movement and flexing of the first beam. The first and second beams are not attached to each other.

The first and second beams are preferably substantially flat or planar, having a low height. This arrangement is particularly suitable for free-standing A.T.M.s which are installed internally in a bank or shop. In this environment, the ATM will be subject to manual attack, with crow-bars, sledge hammers and the like, rather than the longer sustained force of an excavator. By providing limited free movement of the first beam the beam can move, bend and twist to absorb the force of the attack and frustrate any efforts to apply a sustained force with a crow bar or the like to separate the A.T.M. from the first beam or to separate the securing means from the floor.

Preferably, a surrounding frame is provided. This may sit on the floor and be attached to the underside of a plate which is sandwiched between the A.T.M. and the first beam. The frame shields the first and second beams from direct attack. It will also flex or bend when attacked, reducing the transfer of the attacking force to the securing means.

The securing means is attached to the floor by expanding bolts. Preferably the bolts also allow a degree of movement of the bolt in the floor.

The A.T.M. is bolted to the first beam by means of bolts which extend through the floor of the A.T.M. to engage a nut held in a recess in the underside of the first beam.

### DESCRIPTION OF THE PREFERRED EMBODIMENTS

The invention will be further described by way of example only with reference to the accompanying drawings, in which:

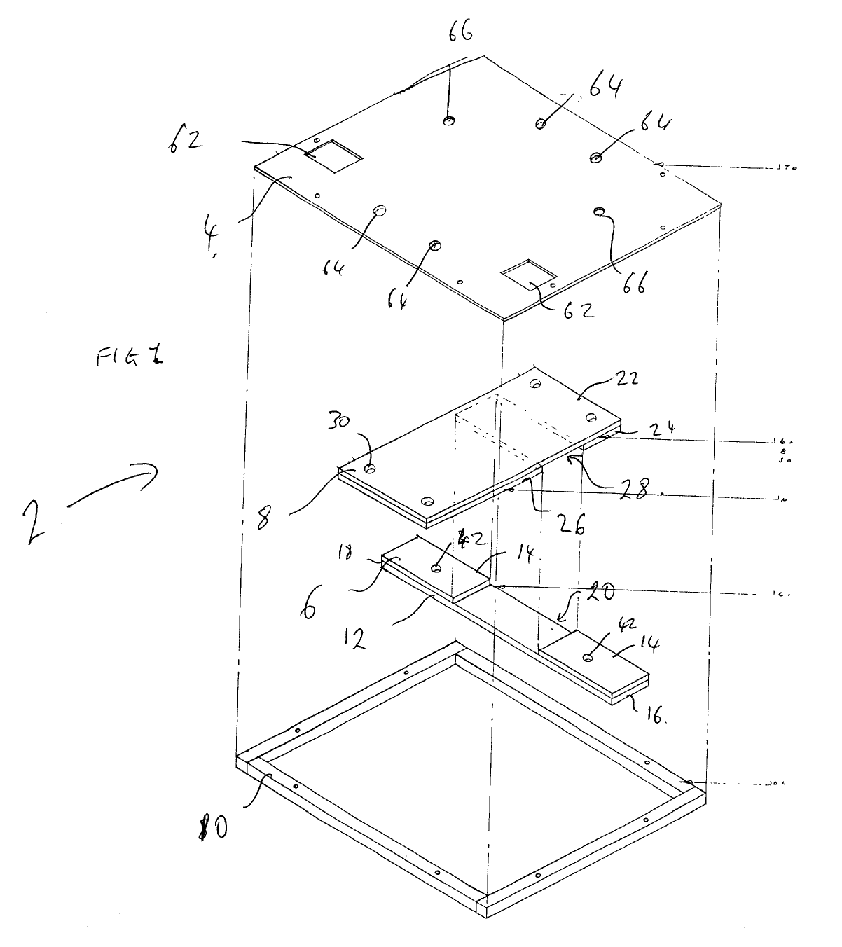

FIG. 1 is an exploded perspective view of an anti-theft device forming an embodiment of the invention;

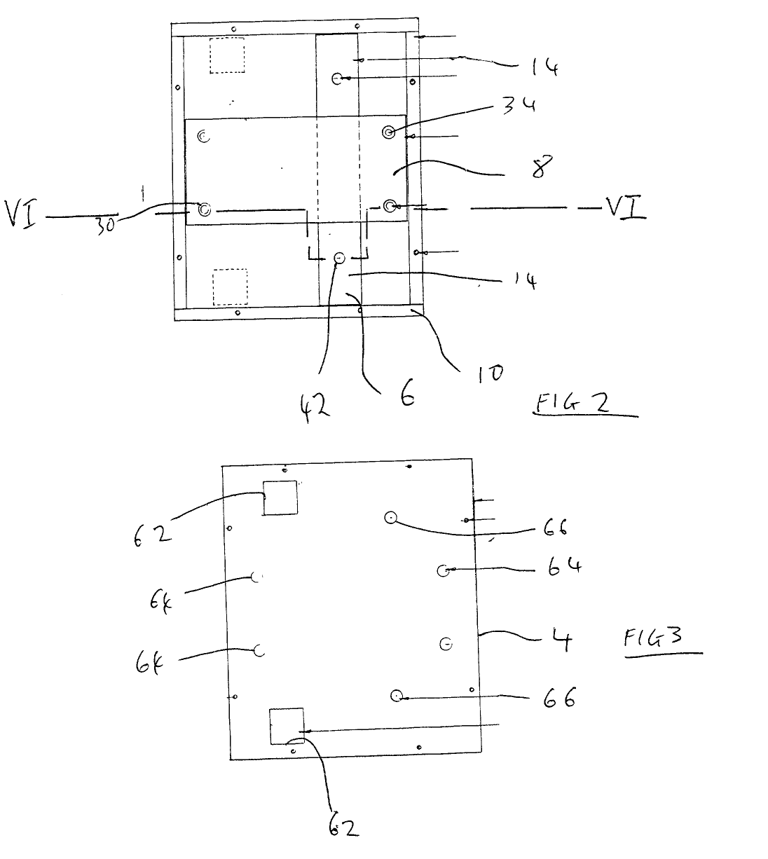

FIG. 2 is a plan view of the device of FIG. 1, with a top plate omitted;

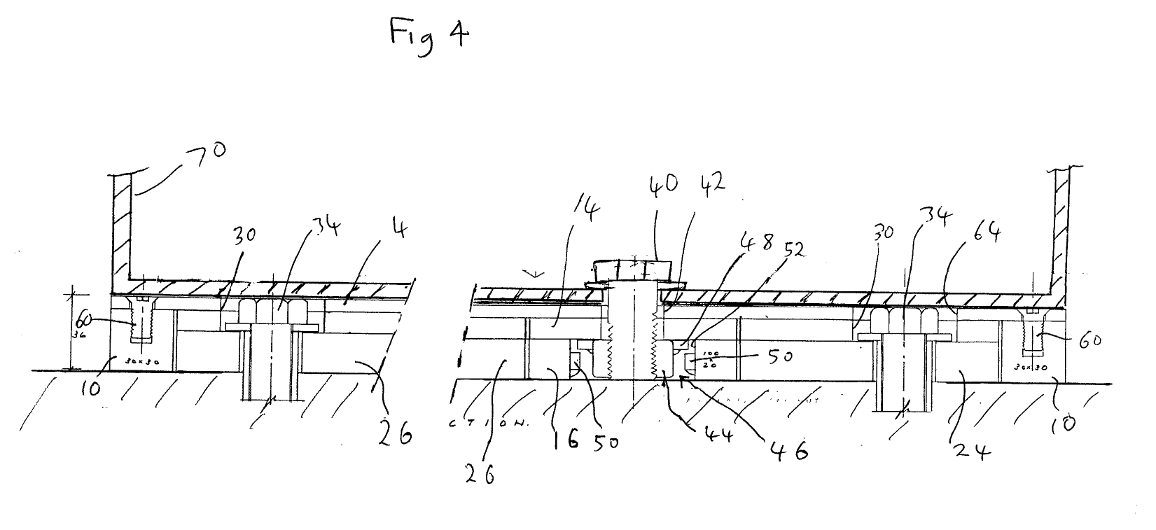

FIG. 3 is a plan view of the top plate of the embodiment of FIG. 1;

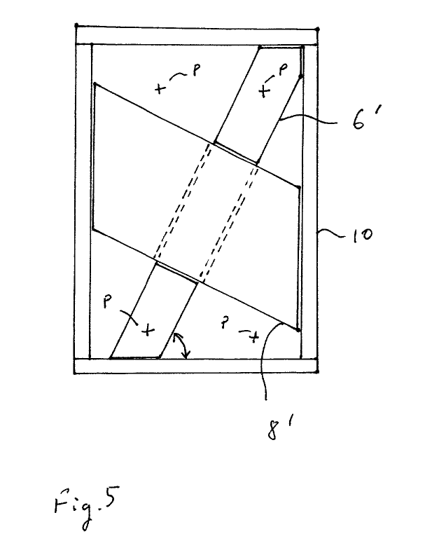

FIG. 4 is a cross-section along the line IV-IV of FIG. 2, with the top plate in position and showing the anti-theft device mounted to a floor with an A.T.M., and

FIG. 5 shows a modification of the embodiment of FIGS. 1 to 4.

Referring firstly to FIG. 1, this shows an anti-theft device of the invention comprising a top plate 4, a first beam 6, a second beam or securing means 8 and a frame 10. All the parts are formed of mild steel.

The first beam 6 is formed of a solid, flat elongate bar section 12, with bar sections 14 welded to it at each end 16, 18 by a continuous butt weld. The end sections 14 define between them a recess or channel 20.

The second beam 8 again comprises a solid, flat bar 22, having end sections 24, 26 butt welded to the underside of the bar 22, to define a channel 28. Channel 20 is wide enough to receive the bar 22, and channel 28 is wide enough to receive the bar 16, so that the two beams 6, 8 will come together in the form of a “halving joint”. Sufficient clearance is allowed in the channel sizes for a small degree of free movement of the bar 12 in the channel 28 in the horizontal plane.

Preferably the bar 12 can move up to 6 mm in either direction within channel 28—that is, when bar 12 is centrally positioned within channel 28 there is at least a 3 mm clearance on either side of the bar. Bar 22 is preferably provided with a similar clearance within channel 20 of bar 12. Other embodiments may be provided with difference clearance limits for movement of the bars within their respective channels, such as at least a 20 mm clearance, at least a 12 mm clearance, at least a 6 mm clearance, at least a 3mm clearance, or at least a 1 mm clearance.

Referring to FIG. 4, the second beam 8 is secured to the floor by four expanding bolts. The bolt head sits in a recess 30 formed by a hole drilled in the plate 22 and bears on the lower plate portions 24 or 26. The preferred bolts are Hilti HSLB No. 20 bolts which can be tightened to a predetermined torque. A head portion of the bolt is sheared off (not shown) when the bolt is tightened to the requisite degree. A remaining head portion 34 allows the bolt to be removed if needed.

With the beam 8 bolted to the floor 36. The first beam 6 is held captive between the beam 8 and the floor 36, but a degree of free movement is allowed by the relative fit between the channels 20, 28.

Referring to FIG. 4, the A.T.M. is secured to the first beam 6 by two safe bolts 40. These pass through apertures 42 in the end portions 14 and engage with nuts 44 which are held captive in an enlarged recess 46 formed in the bar 16.

The nuts 44 are held captive by lugs 48 which are welded to the nut and trapped in the recess 46 by ears 50 welded to the inside wall 52 of the recess 46. The lugs 48 limit the turning movement of the nut 44 in the recess so that the bolt 40 can be tightened onto the nut.

A degree of clearance is provided between the bolt 40 and the apertures 42 in the end pieces 14 and the recess 52 also allows for movement of the nut 44 by a few millimetres. This is to allow for tolerance in the placement of the corresponding holes in the A.T.M machine to ensure that the nut 44 can be aligned with the bolt 40.

Surrounding the cross-piece formed by the beam 6, 8 is the frame 10. Frame 10 is formed by lengths of steel bar which are welded together. The frame 10 is not secured to the floor. Frame 10 is screwed to the underside of the top plate 4, as can be seen in FIG. 4, by screws 60.

The top plate 4 has apertures 62 for cables to be fed to the A.T.M. from the floor. Apertures 64 in the top plate fit over the heads of bolts 34 (see FIG. 4) while apertures 66 allow for the passage of the safe bolts 40.

To install the A.T.M., the first beam 6 is laid on a flat floor area, and the second beam 8 is then laid over the beam 6 and secured to the floor with bolts 34.

The frame 10 and top plate 4 are then secured together with screw 60, and the top plate and frame laid over the beam 6, 8.

The A.T.M. 70 is then mounted on the top plate, and bolts 40 fed through the floor of the A.T.M. to secure the floor to the beam 6.

When the A.T.M. is attacked by rocking it or giving it a heavy sideways blow, the force of the blow will be transmitted through the floor of the A.T.M. and bolts 40 to the first beam 6. First beam 6 will move slightly, and also be able to twist (if the force applied is large enough). This movement and twisting will absorb the force of the impact and so reduce the amount of force which is transmitted through beam 8 to the bolts 34. Bolts 34 in turn are designed to move slightly in the floor, without becoming loose. These bolts are well known and need not be described further here.

Any one seeking to attack the plate 8 directly by levering it from the floor, must first try and remove the outer frame 10. Outer frame 10 is not secured to the floor, but instead is secured to the plate 4. Thus, the frame will bend or buckle, if the A.T.M. wall can also be buckled. But this will not in turn allow transmission of a substantial force to the plate 8 (via the A.T.M. floor) and beam 6.

Thus, the anti-theft device of the invention provides a very low profile design which will resist attack for a substantial period of time.

It will be appreciated that the parts of the anti-theft device are dimensioned to suit the particular A.T.M. model. However, the bar 12 of the first beam 8 and end sections 24, 36 of the second beam 8 are preferably of 20 mm thick steel, and the bar 22 and end sections 14 are of 10 mm thick steel. The top plate 4 is 6 mm thick and of overall dimension about 600 mm×700 mm.

FIG. 5 shows a modification of the embodiment of FIGS. 1 to 4 in which the beams 6′, 8′ are at an angle to the frame 10, otherwise details of the structure are as for the embodiment of FIGS. 1 to 4. The wider beam 8′ overlaps the narrower beam 6′. By angling the beam 6′, the beam 6′ can be positioned to suit the fixing holes which are available on the A.T.M. to be secured. For example, if the fixing holes are at points ‘P’, a diagonal pair of holes can be used. Preferable the beam 6′ is angled at about 50 to 80 degrees to the frame sidewall, and more preferably about 60 to 70 degrees. The two beams 6′, 8′ may be kept generally perpendicular.

Various modifications which lie within the spirit and scope of the invention will occur to those skilled in the art and the invention is not limited to the described embodiments. For example, the invention is not limited to securing an A.T.M. to a floor but can be employed to secure an A.T.M. or other machine to other surfaces, such as walls.

We claim:

1. An anti-theft device for securing an A.T.M. to a floor, comprising a first beam to which the A.T.M. is to be secured, and means for securing the beam to the floor, the securing means allowing limited free movement of the first beam.

2. A device as claimed in claim 1, in which the securing means is a second beam which overlaps the first beam.

3. A device as claimed in claim 2, in which the first beam is positioned in a recess in the second beam.

4. A device as claimed in claim 2, in which the first and second beams overlap at a halving joint.

5. A device as claimed in claim 1, including a top plate which is sandwiched between the A.T.M. and the first beam, and a peripheral frame is attached to the underside of the top plate to inhibit access to the first beam or the securing means.

6. A device as claimed in claim 5, in which the first beam is at an angle to sidewalls of the frame.

7. A device as claimed in claim 5, wherein an A.T.M. is secured to the first beam by a nut and bolt, the nut being housed in a recess in the underside of the first beam.

8. A device as claimed in claim 2, wherein the first beam is from 15 mm to 45 mm thick, preferably from 25 mm to 35 mm, and preferably about 30 mm thick.

9. A device as claimed in claim 2, wherein the second beam is from 15 mm to 45 mm thick, preferably from 25 mm to 35 mm, and preferably about 30 mm thick.

10. A device as claimed in claim 1, wherein the securing means allows a free movement of at least 1 mm, more preferably of at least 5 mm, and more preferably of at least 6 mm.

11. A theft-resistant device for securing a machine to a floor or wall, the device comprising coupled first and second beams configured to resist theft by deforming during an attempt to displace the machine from the floor or wall.

12. A theft-resistant device as claimed in claim 11 wherein said first beam is configured for attachment to the machine and said second beam is configured for attachment to the floor or wall.

13. A theft-resistant device as claimed in claim 12 wherein, when installed, said second beam passes between said first beam and the machine.

14. A low-profile attachment for securing an A.T.M. to a flat surface, the attachment comprising first and second overlying plates coupled by a halving joint.

15. A low-profile attachment as claimed in claim 14 wherein said plates include recesses for receiving securing means for securing the A.T.M. substantially without increasing the profiles of the plates.

16. A theft-resistant device claimed in claim 13, further comprising means to protect one or more sides of the device or attachment from attack.
